(19) United States
(12) Patent Application Publication
(10) Pub. No.: US 2011/0303904 A1
(43) Pub. Date: Dec. 15, 2011

(54) PHOTOVOLTAIC DEVICE AND METHOD OF MAKING SAME

(76) Inventors: Sushobhan Avasthi, Princeton, NJ (US); James C. Sturm, Princeton, NJ (US); Jeffrey Schwartz, Princeton, NJ (US)

(21) Appl. No.: 13/113,606

(22) Filed: May 23, 2011

Related U.S. Application Data
(60) Provisional application No. 61/416,986, filed on Nov. 24, 2010.
(60) Provisional application No. 61/347,666, filed on May 24, 2010.

(51) Int. Cl. H01L 51/46; H01L 31/11

(52) U.S. Cl. 257/40; 257/184; 438/94; 257/E51.026; 257/E51.015; 257/E31.068

(57) ABSTRACT

A photovoltaic device and method of manufacturing is disclosed. In one embodiment, the device includes a silicon layer and first and second organic layers. The silicon layer has a first face and a second face. First and second electrodes electrically are coupled to the first and second organic layers. A first heterojunction is formed at a junction between the one of the faces of the silicon layer and the first organic layer. A second heterojunction is formed at a junction between one of the faces of the silicon layer and the second organic layer. The silicon layer may be formed without a p-n junction. At least one organic layer may be configured as an electron-blocking layer or a hole-blocking layer. At least one organic layer may be comprised of phenanthrenequinone (PQ). A passivating layer may be disposed between at least one of the organic layers and the silicon layer. The passivating layer may be organic. At least one of the organic layers may passivate a surface of the silicon layer. The device may also include at least one transparent electrode layer coupled to at least one of the electrodes.

### CROSS-REFERENCE TO PRIOR FILED APPLICATIONS

This application claims priority to earlier filed provisional applications 61/416,986 and 61/347,666, which were filed on Nov. 24, 2010 and May 24, 2010 respectively, each are incorporated herein in their entirety.

### UNITED STATES GOVERNMENT RIGHTS

This invention was made with government support under NSF-DMR 0819860 and NSF-DMR02-13706 awarded by the National Science Foundation (NSF), as well as #W911NF-05-1-0437 award by ARC. The government has certain rights to this invention.

### FIELD OF INVENTION

This invention relates to the field of photovoltaic devices more specifically to the formation and use of heterojunctions in such devices and in the use of organic materials to create and enhance such heterojunctions.

### BACKGROUND

It has long been desirable to make and use photovoltaic devices. Such devices are useful for detecting electromagnetic radiation, converting electromagnetic radiation to electrical energy, converting electrical energy into light energy and/or other desirable uses.

Photovoltaic devices are sensitive to electromagnetic radiation. In the presence of electromagnetic radiation, photovoltaic devices convert the electromagnetic radiation energy into electrical energy. A solar cell is an example of a photovoltaic device.

Some more efficient forms of photovoltaic devices are constructed from crystalline silicon. However, manufacture of crystalline silicon photovoltaic devices is expensive. Other photovoltaic devices may be manufactured with non-silicon materials for less expense. However, these photovoltaic devices are less efficient in the conversion of electromagnetic radiation into electrical energy. U.S. Pat. No. 7,868,405 B2 issued on Jan. 11, 2011 to Brabec et al. is an example of using organic materials to produce photovoltaic devices from organic material with the aim of reducing manufacturing costs. Brabec discloses an organic heterojunction and fails to produce the efficiency of conversion of electromagnetic radiation into electrical energy observed in state of the art crystalline silicon devices.

There exists a need for a heterojunction for use in photovoltaic devices that reduces manufacturing costs and provides the ability to improve efficiency and performance of the photovoltaic devices.

### SUMMARY OF THE INVENTION

A photovoltaic device and method of manufacturing is disclosed. In one embodiment, the device includes a silicon layer and first and second organic layers. The silicon layer has a first face and a second face. First and second electrodes electrically are coupled to the first and second organic layers. A first heterojunction is formed at a junction between the one of the faces of the silicon layer and the first organic layer. A second heterojunction is formed at a junction between one of the faces of the silicon layer and the second organic layer. The silicon layer may be formed without a p-n junction. At least one organic layer may be configured as an electron-blocking layer or a hole-blocking layer. At least one organic layer may be comprised of phenanthrenequinone (PQ). A passivating layer may be disposed between at least one of the organic layers and the silicon layer. The passivating layer may be organic. At least one of the organic layers may passivate a surface of the silicon layer. The device may also include at least one transparent electrode layer coupled to at least one of the electrodes.

In another embodiment the photovoltaic device includes a silicon layer in contact with an organic layer configured to form a heterojunction. A first electrode is electrically coupled to the silicon layer and a second electrode is electrically coupled to the organic layer. The organic layer is configured as a charge carrier blocking layer. The device may also include a p-n junction formed in the silicon. The organic layer may be undoped and the organic layer may be solution processed. The organic layer may comprise Poly 3-Hexythiophene (P3HT). The device may also include a passivation layer disposed between the organic layer and the silicon layer. The passivation layer may be formed of an organic. The organic layer may be a passivation layer. The organic layer may comprise phenanthrenequinone (PQ). The device may also include at least one transparent electrode layer coupled to at least one of the electrodes.

In another embodiment the photovoltaic device includes a silicon layer and an organic layer configured to form a heterojunction. A first electrode is electrically coupled to the silicon layer and a second electrode is electrically coupled to the organic layer. The silicon layer being formed of materials selected from the group consisting of: silicon alloys, multicrystalline silicon, microcrystalline silicon, protocrystalline silicon, upgraded metallurgical-grade silicon, ribbon silicon, thin-film silicon and combinations thereof. The silicon layer may be formed without a p-n junction. At least one organic layer may be configured as an electron-blocking layer or a hole-blocking layer. At least one organic layer may be comprised of phenanthrenequinone (PQ). A passivating layer may be disposed between at least one of the organic layers and the silicon layer. The passivating layer may be organic. At least one of the organic layers may passivate a surface of the silicon layer. The device may also include at least one transparent electrode layer coupled to at least one of the electrodes.

In another embodiment the photovoltaic device includes a silicon layer in contact with an organic layer to form a heterojunction. A first electrode is electrically coupled to the silicon layer and a second electrode is electrically coupled to the organic layer. The silicon layer may be formed without a p-n junction. The silicon layer is formed with a textured surface. The organic layer may also be formed with a textured surface. The textured surface of the organic layer may conform to the textured surface of the silicon layer. In another embodiment the photovoltaic device includes a silicon layer in contact with an organic layer configured to form a heterojunction. A first electrode is electrically coupled to the silicon layer and a second electrode is electrically coupled to the organic layer. The organic layer is formed with a textured surface.

In another embodiment the photovoltaic device includes a silicon layer in contact with an organic layer configured to form a heterojunction. A first electrode is electrically coupled to the silicon layer and a second electrode is electrically coupled to the organic layer. The organic layer is composed on the silicon layer such that a highest occupied molecular orbital (HOMO) of the organic layer aligns with a top of the valence band edge (Ev) of the silicon layer to facilitate transmission of holes and the lowest unoccupied molecular orbital (LUMO) of the organic layer does not align with a bottom of the conduction band (Ec) of the silicon layer. The silicon layer may be formed without a p-n junction. In another embodiment the photovoltaic device includes a silicon layer in contact with an organic layer configured to form a heterojunction. A first electrode is electrically coupled to the silicon layer and a second electrode is electrically coupled to the organic layer. The organic layer is composed on the silicon layer such that a lowest unoccupied molecular orbital (LUMO) of the organic layer aligns with a bottom of the conduction band edge (Ec) of the silicon layer to facilitate transmission of electrons and a highest occupied molecular orbital (HOMO) of the organic layer does not align with a top of the valence band edge (Ev) of the silicon layer. The silicon layer may be formed without a p-n junction.

In another embodiment the photovoltaic device includes a silicon layer in contact with an organic layer configured to form a heterojunction and passivate a surface of the silicon. A pair of electrodes define a current path through the silicon layer. The silicon layer may be formed without a p-n junction. The organic layer is disposed outside of the current path. The organic layer may be configured to block at least one charge carrier. The organic layer may comprise phenanthrenequinone (PQ).

In another embodiment a method of forming a photovoltaic device is disclosed. The method includes depositing first and second organic layers on a silicon layer, the silicon layer having a first face and a second face. First and second electrodes are electrically coupled to the first and second organic layers. A first heterojunction is formed at a junction between the first face of the silicon layer and the first organic layer. A second heterojunction is formed at a junction between the second face of the silicon layer and the second organic layer. The photovoltaic device may be fabricated at a temperature below 500° C. The silicon layer may be formed without a p-n junction.

In another embodiment a method of forming a photovoltaic device includes depositing an organic layer on a silicon layer and forming a heterojunction. A first electrode is electrically coupled to the silicon layer. A second electrode is electrically coupled to the organic layer. The organic layer is configured as a charge carrier blocking layer. The photovoltaic device may be fabricated at a temperature below 500° C. The silicon layer may be formed without a p-n junction.

In another embodiment a method of forming a photovoltaic device includes depositing an organic layer on a silicon layer and forming a heterojunction. A first electrode is electrically coupled to the silicon layer. A second electrode is electrically couple to the organic layer. The silicon layer is formed of materials selected from the group consisting of: silicon carbide, multicrystalline silicon, microcrystalline silicon, protocrystalline silicon, upgraded metallurgical-grade silicon, ribbon silicon, thin-film silicon and combinations thereof. The photovoltaic device may be fabricated at a temperature below 500° C. The silicon layer may be formed without a p-n junction.

### BRIEF DESCRIPTION OF THE FIGURES

FIG. 1.1 is a schematic of the function of a photovoltaic device in light conditions and dark conditions;

FIG. 1.2 is a band-diagram of the photovoltaic device of FIG. 1.1 under illumination and connected to external load;

FIG. 1.3 is a band-diagram of the photovoltaic device of FIG. 1.1 under dark and an external voltage;

FIG. 2.1 is a diagram showing band-alignment of an electron-blocking layer;

FIG. 2.2 is a diagram showing band-alignment of a hole-blocking layer;

FIG. 3.1 is a schematic of a photovoltaic device embodiment with a p-n junction and an electron blocking layer;

FIG. 3.2 is a band-diagram of the p-n junction of FIG. 3.1 under dark, connected to an external voltage;

FIG. 4.1 is a schematic of a photovoltaic device embodiment with a p-n junction and a hole blocking layer;

FIG. 4.2 is a band-diagram of the p-n junction of FIG. 4.1 under dark and connected to an external voltage;

FIG. 5.1 is a schematic of a photovoltaic device embodiment with a p-n junction, a hole blocking layer and passivation;

FIG. 5.2 is an embodiment of a photovoltaic device with a p-n junction, an electron blocking layer and passivation;

FIG. 6.1 is a schematic of a photovoltaic device embodiment having a metal-organic-silicon junction and an electron blocking layer on n-type silicon;

FIG. 6.2 is a band-diagram of the photovoltaic device of FIG. 6.1 in dark under and connected to an external voltage;

FIG. 7.1 is a schematic of a photovoltaic device embodiment having a metal-organic-silicon junction and a hole blocking layer on p-type silicon;

FIG. 7.2 is a band-diagram of the photovoltaic device of FIG. 7.1 in dark under and connected to an external voltage;

FIG. 8.1 is a schematic diagram showing the structure of a metal-silicon “Schottky” junction photovoltaic device embodiment (solar cell) on n-type silicon without a p-n junction;

FIG. 8.2 is a schematic diagram showing the structure of a metal-P3HT-silicon heterojunction photovoltaic device embodiment (solar cell) on n-type silicon without a p-n junction;

FIG. 8.3 is a graph showing the current-voltage characteristics of the photovoltaic devices of FIGS. 8.1 and 8.2;

FIG. 9.1 is a schematic of a photovoltaic device with a metal-organic-silicon junction, an electron-blocking layer and a hole-blocking back-surface-field on n-type silicon;

FIG. 9.2 is a band-diagram of the photovoltaic device of FIG. 9.1 under dark and connected to an external voltage;

FIG. 10 is a schematic of a silicon-organic heterojunction photovoltaic device embodiment (solar cell) with an electron blocking layer, a hole-blocking layer and passivated silicon surfaces;

FIG. 11.1 is a schematic representation showing the improvement of reflection offered by a textured solar cell over that of a non-textured solar cell;

FIG. 11.2 is a schematic representation showing improved absorption of a textured solar cell over a non-textured solar cell;

FIG. 11.3 is a schematic representation showing improved absorption of a textured solar cell with a back-reflector over a non-textured solar cell with a back-reflector;

FIG. 12.1 is a schematic representation of a textured photovoltaic device embodiment;

FIG. 12.2 is a schematic representation of a another textured photovoltaic device embodiment;

FIG. 12.2 is a schematic representation of another textured photovoltaic device embodiment;

FIG. 13.1 is a schematic representation (top view) of the structure of a top transparent electrode on top of a P3HT-silicon heterojunction photovoltaic device embodiment (solar cell) on n-type silicon without a p-n junction;

FIG. 13.2 is a cross sectional view of the photovoltaic device of FIG. 13.1;

FIG. 14.1 is a schematic representation of a portion of photovoltaic device with a conventional passivation layer deposited on a silicon layer; and

FIG. 14.2 is a schematic representation of a portion of photovoltaic device with passivation by an organic layer, such as PQ.

### DETAILED DESCRIPTION OF THE INVENTION

### Definitions

“homojunction” as used herein is a p-n junction made out of the same material.

“heterojunction” as used herein is an interface between materials with different electronic band structures.

“carrier blocking layer” as used herein refers to either an electron blocking layer, a hole blocking layer or a layer which blocks both electrons and holes.

“electron-blocking layer” as used herein is a material that allows the through transport of holes and prevents the through transport of electrons to and from silicon. This is may be achieved with an approximate alignment of “highest occupied molecular orbital” (HOMO)/valence-band edge (Ev) of the material with the valence-band edge (Ev) of silicon and a substantially higher “lowest unoccupied molecular orbital” (LUMO)/conduction-band edge (Ec) of the material than the conduction band edge (Ec) of the silicon (see e.g., FIG. 2.1).

“hole-blocking layer” as used herein is a material that allows the through transport of electrons and prevents the through transport of holes to and from silicon. This may be achieved with an approximate alignment of LUMO/conduction-band edge (Ec) of the material with the conduction-band edge (Ec) of silicon, and a substantially lower HOMO/valence-band edge (Ev) of the material than the valence-band edge of the silicon (Ev) (see e.g., FIG. 2.2).

“Surface passivation” as used herein is the removal of electrically active midgap defects on the surface of a semiconductor.

“Low-temperatures” as used herein are temperatures below about 500° C., and more preferably below about 160° C.

The basic physics of photovoltaics is typically a two-step process 1) the ability to absorb electromagnetic radiation and generate charges and 2) use an internal electric field to separate out the positive charges (holes) and negative charges (electrons). Inorganic solar cells typically are made from crystalline or multicrystalline materials to absorb light. To separate the photo-generated charge carriers, a p-n junction is fabricated in the device which generates the internal electric field. The photoabsorption and charge-separation gives the device its open circuit voltage (V_{OC}) and short circuit current (I_{SC}), allowing it to generate electricity from light. However, making a p-n junction is expensive, especially in silicon. The creation of the p-n junction is a high-temperature, energy intensive and expensive step.

A photovoltaic device under light may be treated as a diode where the current-density (J) depends on the voltage across the electrodes (V) as per the following function:

$$J = {J}_{0} ( \frac{qV}{{e}^{nkT}} - 1 ) - {J}_{SC}$$

The voltage output of a solar cell at open-circuit condition (J=0), the open-circuit voltage (V_{OC}), may be characterized using the following formula:

$${V}_{OC} = \frac{kT}{q} ln ( \frac{{J}_{SC}}{{J}_{0}} )$$

Where: J_{SC} is the short-circuit current density and V_{OC} is the open-circuit voltage: two important parameters in photovoltaic devices. Once the parameter J_{SC} reaches its theoretical maximum, further increase in V_{OC} requires reducing J₀.

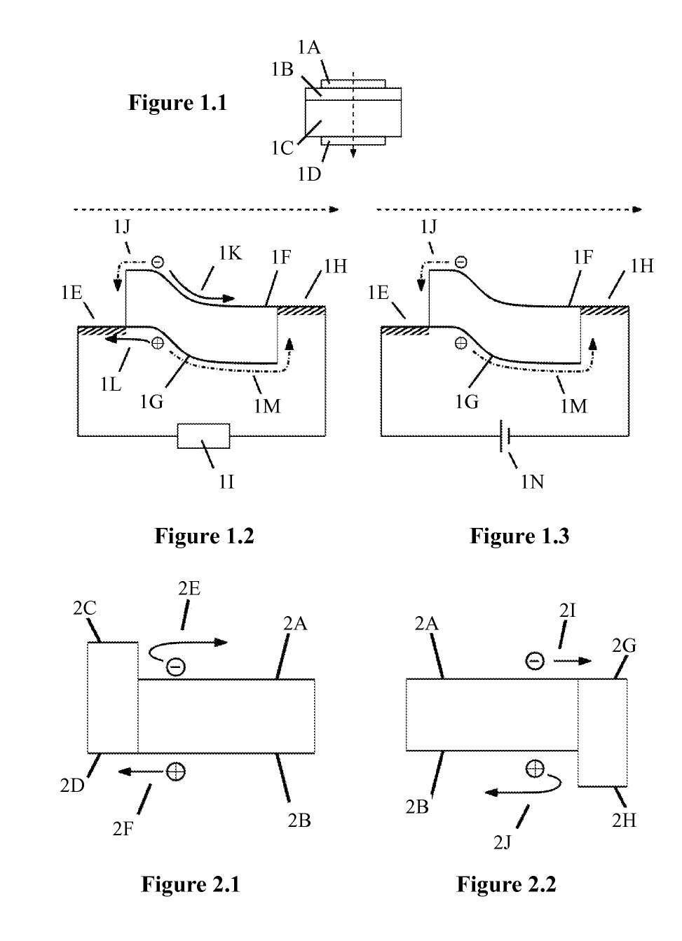

FIG. 1.1 shows the structure of a photovoltaic device with schematics of its function in light conditions (FIG. 1.2) and dark conditions (FIG. 1.3). The photovoltaic device includes an: anode electrode 1A, a p-type silicon layer 1B, an n-type silicon layer 1C and a cathode electrode 1D. At least one of the electrodes 1A, 1D may be transparent. Under exposure to electromagnetic radiation, some current pathways generate power while others are “loss” pathways. It is desirable to determine the cause of loss and reduce loss within photovoltaic devices. FIG. 1.2 is a band-diagram of FIG. 1.1 under illumination and connected to external load 1I. FIG. 1.3 is a band-diagram of FIG. 1.1 under dark and connected to an external voltage 1N. The following reference numbers apply:
1E: Anode electrode Fermi level
1F: Bottom of the conduction-band edge of silicon (Ec);
1G: Top of the valence-band edge of silicon (Ev);
1H: Cathode electrode Fermi level;
1I: External Load;
1J: Electron recombination current (loss mechanism);
1K: Light-induced electron current;
1L: Light-induced hole current;
1M: Hole recombination current (loss mechanism); and
1N: External applied voltage to device in dark.

It was determined that the “loss” pathways (1J and 1M) are precisely what are active in the absence of electromagnetic radiation, e.g., in the dark, when an external voltage was applied (see e.g., FIG. 1.3). It was considered that this “dark-current” could be examined by measuring the J₀ of the photovoltaic device in the absence of electromagnetic radiation. Thus, it was found that J₀ is an effective measure of many of the recombination loss mechanisms of a solar cell. Through the examination of J₀, the recombination losses in a photovoltaic device were measured. By reducing J₀, open circuit voltage is increased when the photovoltaic device is exposed to electromagnetic radiation and the overall efficiency of the photovoltaic device is improved.

FIG. 2.1 is a diagram showing band-alignment between a silicon layer and an electron-blocking layer. FIG. 2.2 is a diagram showing band-alignment between a silicon layer and a hole-blocking layer. The following reference numbers apply:
2A: Bottom of the conduction-band edge of silicon (Ec);
2B: Top of the valence-band edge of silicon (Ev);
2C: Electron-blocking layer's LUMO or bottom of the conduction-band edge;
2D: Electron-blocking layer's HOMO or top of the valence-band edge;
2E: Electron transport is impeded;
2F: Holes transport is facilitated;
2G: Hole blocking layer's LUMO or bottom of the conduction-band edge;
2H: Hole blocking layer's HOMO or top of the valence-band edge;
2I: Electron transport is facilitated; and
2J: Hole-transport is impeded.

It was determined that one way to reduce J₀ in a silicon p-n junction photovoltaic device is by introducing an electron-blocking layer 3B between the p-side of the silicon p-n junction and the anode electrode 3A.

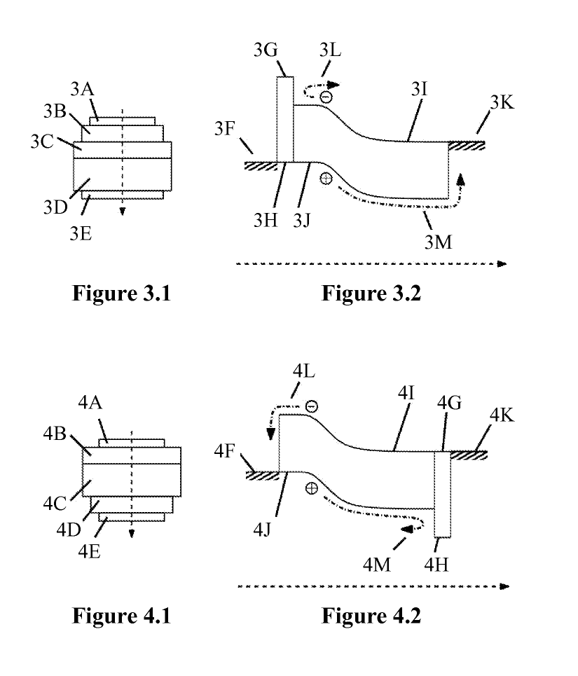

FIG. 3.1 is a schematic of a photovoltaic device embodiment with a p-n junction and an electron blocking layer. The photovoltaic device includes an anode electrode 3A, an electron-blocking layer 3B, a p-type silicon layer 3C, an n-type silicon layer 3D and a cathode electrode 3E. At least one of the electrodes 3A, 3E may be transparent.

FIG. 3.2 is a band-diagram of the p-n junction of FIG. 3.1 under dark, connected to an external voltage. The following reference numbers apply:
3F: Anode electrode Fermi level;
3G: Electron-blocking layer's LUMO or bottom of the conduction-band edge;
3H: Electron-blocking layer's HOMO or top of the valence-band edge;
3I: Conduction-band edge of silicon;
3J: Valence-band edge of silicon;
3K: Cathode electrode Fermi level;
3L: Electron recombination current is reduced (loss mechanism); and
3M: Hole recombination current (loss mechanism).

It was found that the electron blocking layer 3B suppresses the loss due to electron recombination at the p-side contact of p-n diode (FIG. 3.2). One such electron-blocking layer can be an organic material such as N,N′-diphenyl-N,N′-bis(3-methyl-phenyl)-1,1′biphenyl-4,4′diamine (TPD) [S. Avasthi et al. DOI: 10.1109/PVSC.2009.5411419].

In was determined that another way to reduce J₀ in a silicon p-n junction photovoltaic device is by introducing a hole blocking layer on the n side of the silicon p-n junction. FIG. 4.1 is a schematic of a photovoltaic device embodiment with a p-n junction and a hole blocking layer. The photovoltaic device includes an anode electrode 4A, a p-type silicon layer 4B, an n-type silicon layer 4C, a hole-blocking layer 4D and a cathode electrode 4E. At least one of the electrodes 4A, 4E may be transparent

FIG. 4.2 is a band-diagram of the p-n junction of FIG. 4.1 under dark and connected to an external voltage. The following reference number apply:
4F: Anode electrode Fermi level;
4G: Hole-blocking layer's LUMO or bottom of the conduction-band edge;
4H: Hole-blocking layer's HOMO or top of the valence-band edge
4I: Conduction-band edge of silicon;
4J: Valence-band edge of silicon;
4K: Cathode electrode Fermi level;
4L: Electron recombination current (loss mechanism); and
4M: Hole recombination current is reduced (loss mechanism).

It was found that the hole-blocking layer 4D suppresses the loss due to hole recombination at the n-side contact of p-n junction (see e.g., FIG. 4.2). In some embodiments, the hole blocking layer can be an organic material.

Unsatisfied valencies of the silicon atoms at the silicon surface cause electrically active midgap defect states. These “surface-states” on the silicon surface also lead to recombination losses that increase J₀. Therefore, it was determined that J₀ is further reduced by removing the surface-states, e.g., passivating the silicon surface. It was determined that surface-states are removed by satisfying the unsatisfied valencies on the silicon surface. It was determined that a material that chemically interacts with unsatisfied silicon valencies on the surface of the silicon, removes surface-states and passivates the surface. This layer is positioned between the silicon surface and the carrier blocking layer, within the path of the current flow. Therefore, it should not impede the transport of carriers through it. One specific example using an organic material, is disclosed in Applied Physics Letters 96, 222109 (2010) doi: 10.1063/1.3429585 and S. Avasthi et al., Surface Science (2011) doi:10.1016/j.susc.2011.04.024 which are incorporated herein in their entirety). The pi-conjugated organic material, phenanthrenequinone (herein after referred to as “PQ”), has been shown to passivate silicon surfaces and improve efficiency in photovoltaic devices.

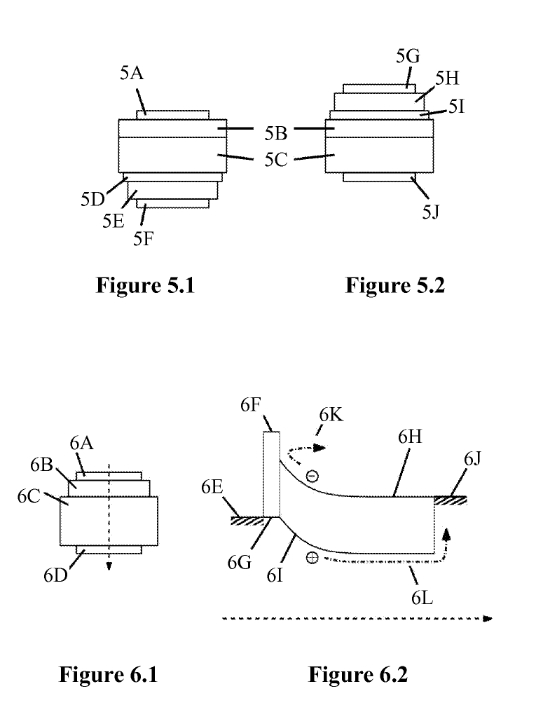

FIG. 5.1 is a schematic of a photovoltaic device embodiment with a p-n junction, a hole blocking layer and passivation. The photovoltaic device has an anode electrode 5A, a p-type silicon layer 5B, an n-type silicon layer 5C, a passivation layer 5D, a hole-blocking layer 5E and a cathode electrode 5F. At least one of the electrodes 5A, 5F may be transparent. FIG. 5.2 is an embodiment of a photovoltaic device with a p-n junction, an electron blocking layer and passivation. The photovoltaic device has an anode electrode 5G, an electron-blocking layer 5H, a passivation layer 5I, a p-type silicon layer 5B, an n-type silicon layer 5C and a cathode electrode 5J. At least one of the electrodes 5G, 5J may be transparent.

The passivating layer 5I, 5D can be used in conjunction with the electron-blocking layer 5H on the p side (FIG. 5.2) or with the hole-blocking layer 5E on the n side (FIG. 5.1) to further reduce the J₀ of the silicon p-n junction photovoltaic device. It should be understood that the carrier-blocking layers (both electron and hole) may also be passivating layers that remove defect states on the silicon, e.g., one layer may achieve both functions.

J₀ can be further reduced by using a combination of the techniques described above. For example, a silicon p-n junction photovoltaic device can achieve significant reduction in J₀ by incorporating an electron blocking layer between the p-type silicon and its electrode, a hole blocking layer between the n-type silicon and its electrode, and passivating layers on both sides (if separate passivating layers are necessary).

It is possible to make carrier blocking layers and passivating layers on silicon using amorphous silicon (and amorphous silicon alloys). Furthermore, this method may be applied to make a silicon photovoltaic device. Typically, the crystalline silicon substrate is n-type, onto which a thin layer of intrinsic amorphous silicon is grown. This is followed by the growth of a layer of p-type amorphous silicon. This junction is referred to as a Heterojunction with an Intrinsic Thin layer or a “HIT” junction (see Tanaka M. et al., 2003, Proceedings of the 3^{rd} World Conference on Photovoltaic Energy Conversion, Vol. 1, pp 955-958 doi: 10.1109/WCPEC.2003.1305441; and, Tanaka M. et al. 1993, Jpn. J. Appl. Phys. Vol. 31, pp. 3518-3522, both of which are hereby incorporated by reference in their entirety). On the other side of the crystalline silicon, another intrinsic amorphous silicon layer is deposited. On the intrinsic layer, an n-type amorphous silicon layer is grown. This creates a p-n-n junction. This method of creating a passivated contact is referred to as a back surface. The method helps to reduce minority carrier recombination and increase efficiencies. Depositing electrodes on the final layers of amorphous silicon completes the HIT junction. Metal or transparent conducting polymers are suitable for the electrode. While the HIT junction is effective, the required use of amorphous silicon adds a high degree of complexity to the construction of the HIT junction and with the complexity a significant cost is added. The construction requires the use of plasma-enhanced chemical vapor deposition. This process must be perform under vacuum conditions, utilizing a plasma system and involves dangerous gases. It is desirable to passivate the silicon by a less costly and safer method.

In conventional silicon p-n junction photovoltaic devices, the electric field that separates and facilitates the collection of the photo-generated carrier is created by the p-n junction. The p-n junction is fabricated by a high temperature and cost intensive diffusion process. This costly step is eliminated by using a metal-silicon “Schottky” junction, instead of a p-n junction, to create the electric field [S. M. Sze, Physics of semiconductor devices (Wiley, New York, 1969), Second edition Ch. 8.]. However, the resulting J₀ is very high due to a large majority carrier current, leading to devices with lower V_{OC} and lower efficiencies.

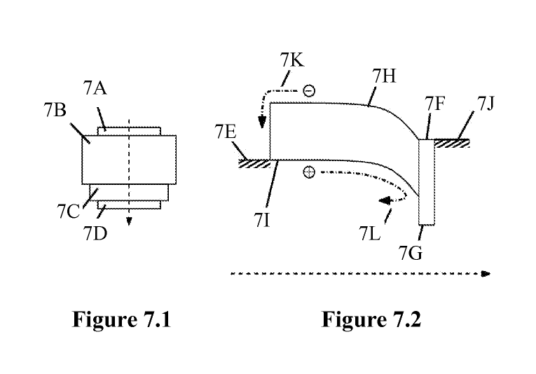

It was determined that the high J0 can be also reduced by enhancing the “Schottky” junction by incorporating a carrier blocking layer to block the majority carrier current, i.e. electron blocking layer 6B for n-type silicon substrate (FIG. 6.1) and hole blocking layer for p-type silicon substrate 7C (FIG. 7.1). The carrier blocking layers may be organic materials. The resulting metal/organic/silicon heterojunction can effectively replace p-n junctions in conventional photovoltaic devices and create internal electric field to separate and facilitate the collection of photogenerated carriers.

FIG. 6.1 is a schematic of a photovoltaic device embodiment that does not have a p-n junction but instead uses a metal-organic-silicon junction and an electron blocking layer on n-type silicon to separate photogenerated charge carriers. The photovoltaic device has an anode electrode 6A, an electron-blocking layer 6B, an n-type silicon layer 6C and a cathode electrode 6D. At least one of the electrodes 6A, 6D may be transparent. FIG. 6.2 is a band-diagram of the photovoltaic device of FIG. 6.1 in dark under and connected to an external voltage. The following reference numbers apply:
6E: Anode electrode Fermi level;
6F: Electron-blocking layer's LUMO or bottom of the conduction-band edge;
6G: Electron-blocking layer's HOMO or top of the valence-band edge;
6H: Conduction-band edge of silicon;
6I: Valence-band edge of silicon;
6J: Cathode electrode Fermi level;
6K: Electron recombination current is reduced (loss mechanism); and
6L: Hole recombination current (loss mechanism).

FIG. 7.1 is a schematic of a photovoltaic device embodiment that does not have any p-n junction but instead uses a metal-organic-silicon junction and a hole blocking layer on p-type silicon to separate photogenerated charge carriers. The photovoltaic device has an anode electrode 7A, p-type silicon layer 7B, hole-blocking layer 7C and cathode electrode 7D. At least one of the electrodes 7A, 7D may be transparent. FIG. 7.2 is a band-diagram of the photovoltaic device of FIG. 7.1 in dark under and connected to an external voltage. The following reference numbers apply:
7E: Anode electrode Fermi level;
7F: Hole-blocking layer's LUMO or bottom of the conduction-band edge;
7G: Hole-blocking layer's HOMO or top of the valence-band edge;
7H: Conduction-band edge of silicon;
7I: Valence-band edge of silicon;
7J: Cathode electrode Fermi level;
7K: Electron recombination current (loss mechanism); and
7L: Hole recombination current is reduced (loss mechanism).

By using an organic carrier blocking layer in the heterojunction structure mentioned above, the photovoltaic device may be produced with substantially less manufacturing cost than conventional p-n junction based photovoltaic devices. The lower costs are possible because the high temperature and expensive diffusion process required in the formation of p-n junction is replaced by the room-temperature and low cost application of organic layer onto silicon (via spin coating, spray coating or lamination). Due to the wide array of organic material available, photovoltaic devices containing such heterojunctions photovoltaic device with at least one organic layer may be optimized to specific purposes and greater efficiency than possible from silicon homojunctions.

One embodiment of a silicon-organic heterojunction photovoltaic device includes an organic layer of Poly 3-Hexythiophene (hereinafter referred to as ‘P3HT’) as the electron blocking layer on n-type silicon substrate. However, it should be understood that there is a wide array of organic molecules that could be substituted for P3HT. The P3HT-silicon interface satisfies the two key band alignment criteria for efficient photovoltaic operation: a) large barrier at the conduction-band to block the photo-generated electrons in silicon from recombining at the metal and b) small valence-band barrier so that, unlike electrons, the photo-generated holes easily flow across the interface to be collected at the anode.

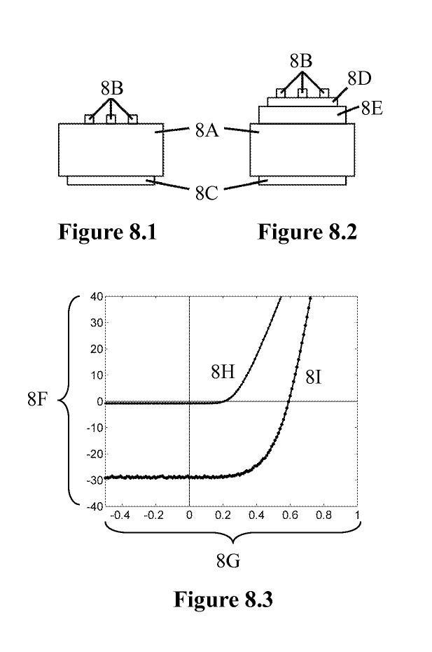

FIG. 8.1 shows the structure of a metal-silicon “Schottky” junction photovoltaic device on n-type silicon with no p-n junction. FIG. 8.2 shows the structure of a metal-P3HT-silicon heterojunction solar cell on n-type silicon with no p-n junction. The following reference numbers apply:
8A: n-type silicon;
8B: Metal Grid (anode);
8C: Cathode electrode;
8D: Transparent conductor (a part of the anode); and
8E: P3HT layer (the electron-blocking organic).

FIG. 8.3 shows the current-voltage characteristics of structures in shown in FIGS. 8.1 and 8.2. The following reference numbers apply:
8F: The vertical axis is the current density measured in mA/cm2;
8G: The horizontal axis is the supplied voltage measured in volts; and
8H: Current-voltage characteristic of structure in FIG. 8.1 under illumination.
8I: Current-voltage characteristic of structure in FIG. 8.2 under illumination.

Due to reduced J₀, compared to metal-silicon Schottky junctions (FIG. 8.1), the P3HT-silicon heterojunctions (FIG. 8.2) improve the photovoltaic performance and the open-circuit voltages increased from 0.30 V for Schottky junctions to 0.59 V for metal-organic-silicon heterojunction photovoltaic devices (FIG. 8.3).

Previous attempts to create silicon-organic heterojunctions for photovoltaic applications have used heavily-doped “metal-like” organic materials, which function as transparent conductors. For instance, the experiments described in Camaioni et al. [Synthetic Metals 85 (1997) 1369-1370], Sailor et al [Science 249, 1146 (1990)] and Wang et al. [Applied Physics Letters 91 (2007)] utilize doped near-metallic organic layers. Camaioni et al., Sailor et al., and Wang et al. are hereby incorporated by reference in their entirety. Meanwhile, the heterojunctions of silicon and organic as described herein use semiconducting organic layers.

Also most previous attempts to construct a silicon-organic heterojunction have relied on mono-crystalline silicon (see, Wang et al, (2007)). It is described herein that heterojunctions may be produced by these methods using other types of silicon. For instance, it is envisioned the construction of heterojunctions photovoltaic devices using various silicon alloys (SiGe, SiC, SiGeC, etc), multicrystalline silicon, microcrystalline silicon, protocrystalline silicon, upgraded metallurgical-grade silicon, ribbon silicon, thin-film silicon, and combinations thereof. It is also envisioned that such heterojunctions of these types of silicon may be used in photovoltaic devices, including solar cells, diodes, capacitor and transistors.

In metal-silicon “Schottky” devices minority carrier currents are much smaller than majority carrier recombination currents; e.g. in Schottky devices on n-type silicon, electron current is much larger than hole current. However, in metal-organic-silicon heterojunction devices of FIGS. 6.1 and 7.1, the majority carrier current, electron and hole current respectively, is reduced to a level where minority carrier recombination current, hole and electron current respectively, is larger. Increased silicon doping and increased minority carrier recombination lifetimes in silicon diminish the minority carrier recombination current. One way to realize higher minority carrier recombination lifetimes is to use better quality silicon substrates such as Float-zone silicon.

It is envisioned that minority carrier recombination currents in the metal-organic-silicon heterojunction photovoltaic device can be further reduced by adding another carrier blocking layer (hole blocking for n-type silicon substrate and electron blocking for p-type silicon substrate) at the other end of the device. This additional carrier blocking layer reduces the losses due to recombination of minority carriers (holes in n-type silicon and electrons in p-type silicon) and improves V_{OC} and the overall efficiency of the photovoltaic device. The second blocking layer can be thought of as the replacement for the back surface field used in conventional silicon p-n junction photovoltaic devices. This blocking layer may be made of organic materials.

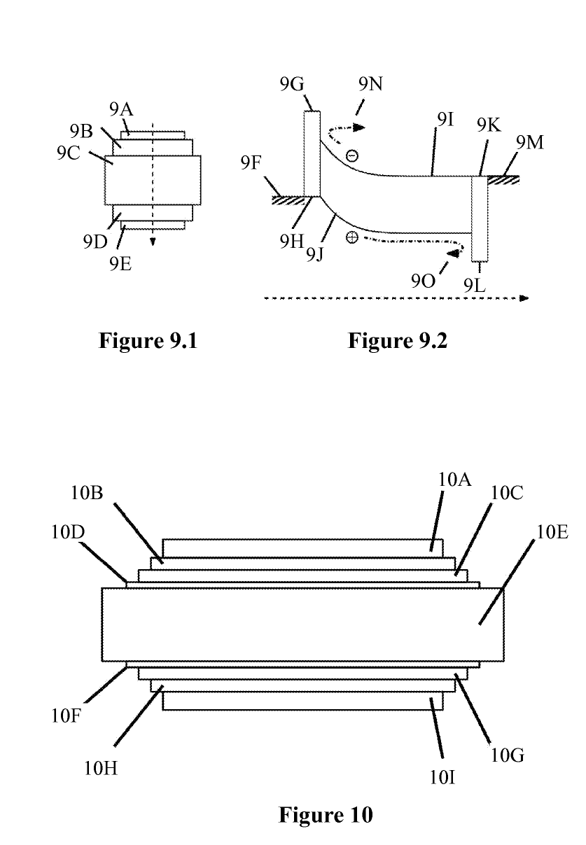

FIG. 9.1 is a schematic of a photovoltaic device with a metal-organic-silicon heterojunction, an electron-blocking layer and a hole-blocking back-surface-field on n-type silicon. The photovoltaic device has an anode electrode 9A, an electron-blocking layer 9B, an n-type silicon layer 9C, a hole-blocking layer 9D and a cathode electrode 9E. At least one of the electrodes 9A, 9E may be transparent. FIG. 9.2 is a band-diagram of the photovoltaic device of FIG. 9.1 under dark and connected to an external voltage. The following reference numbers apply:
9F: Anode electrode Fermi level;
9G: Electron-blocking layer's LUMO or bottom of the conduction-band edge;
9H: Electron-blocking layer's HOMO or top of the valence-band edge;
9I: Conduction-band edge of silicon;
9J: Valence-band edge of silicon;
9K: Hole-blocking layer's LUMO or bottom of the conduction-band edge;
9L: Hole-blocking layer's HOMO or top of the valence-band edge;
9M: Cathode electrode Fermi level;
9N: Electron recombination current is reduced (loss mechanism); and
9O: Hole recombination current is reduced (loss mechanism).

Minority carrier currents may be further reduced by passivation of the silicon surface with a material that has the appropriate chemical bonding structure. This can be achieved with a set of materials which includes but is not limited to organics. This passivating layer is positioned between the silicon surface and the carrier blocking layer, within the path of the current flow. Therefore, it should not impede the transport of carriers through it. For example, PQ has been shown to passivate silicon surfaces and improve efficiency in photovoltaic devices [S. Avasthi, et al. doi: 10.1063/1.3429585]. The passivating layer may be incorporated as part of the silicon-organic heterojunction to further reduce the J₀ and further improve the performance of the photovoltaic devices.

FIG. 10 is a schematic of a silicon-organic heterojunction photovoltaic device embodiment (solar cell) with an electron blocking layer, a hole-blocking layer and passivated silicon surfaces. The device has anode electrode 10A, an optional intermediate layer-1 10B, an electron-blocking organic layer 10C, an optional passivation layer 10D that allows conduction of holes, a silicon layer 10E, an optional passivation layer 10F that allows conduction of electrons, a hole-blocking organic layer 10G, an optional intermediate layer-2 10H and a cathode electrode 10I. At least one of the electrodes 10A, 10I may be transparent.

It should be noted that the passivating layer that removes defect states on the silicon surface may also be the carrier blocking layers (either electron or hole) i.e. one layer can achieve both functions.

The passivation of silicon with organic material may be conducted at low temperature without use of an ultra-clean oven or other expensive equipment. Therefore, use of an organic to passivate silicon surfaces not only offers increased efficiency of performance but also lower manufacturing costs and less capitol expense for manufacturing.

It is also envisioned that heterojunctions photovoltaic device as described above, provides an opportunity to improve efficiency of the photovoltaic device through the use of surface texturing. Surface texturing in a photovoltaic device refers to roughening of the silicon surface with several micron sized random structures and it generally results an increase in the short-circuit current and the overall efficiency. This increase arises from three mechanisms:

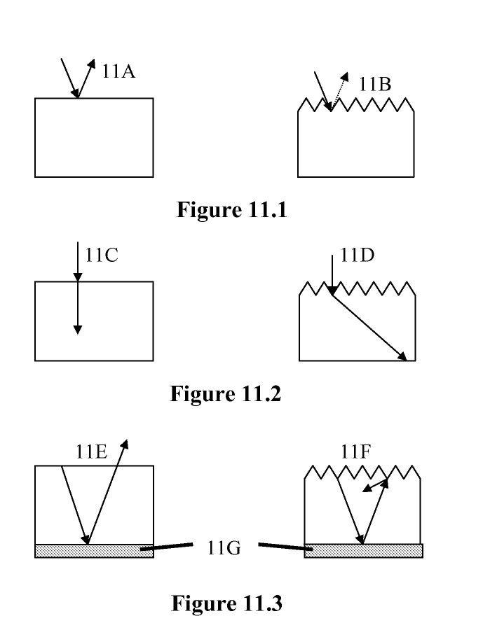

i) Textured surfaces are angled so that reflected incident light rays are likely to strike another surface and enter the cell, reducing the overall reflection from the silicon surface (see e.g., FIG. 11.1). Reference number 11A shows how un-textured silicon surface reflects light. Reference number 11B shows how a textured silicon surface reduces light reflection.

ii) Refracted light rays entering the cell propagate at an angle less than normal to the plane of the cell, allowing them to travel longer distances in the absorbing material before having a chance to escape. This increases the probability of absorption (see FIG. 11.2). Reference number 11C shows that in un-textured silicon most light enters normally. Reference number 11D shows that in textured silicon surface light enters at an angle.

iii) Longer wavelength light is not efficiently absorbed by the silicon. One solution is thicker silicon wafers, but that solution is expensive. The alternative is to have reflector material on the backside, e.g., back-reflectors (usually backside metal) which reflect the un-absorbed light back towards the front surface. The textured front surface increases the probability that this light will be internally reflected, improving the probability of absorption (see FIG. 11.3). Reference number 11E shows how in un-textured silicon light reflected from back reflector is lost. Reference number 11E shows how in textured silicon light reflected from back reflector 11G is scattered back.

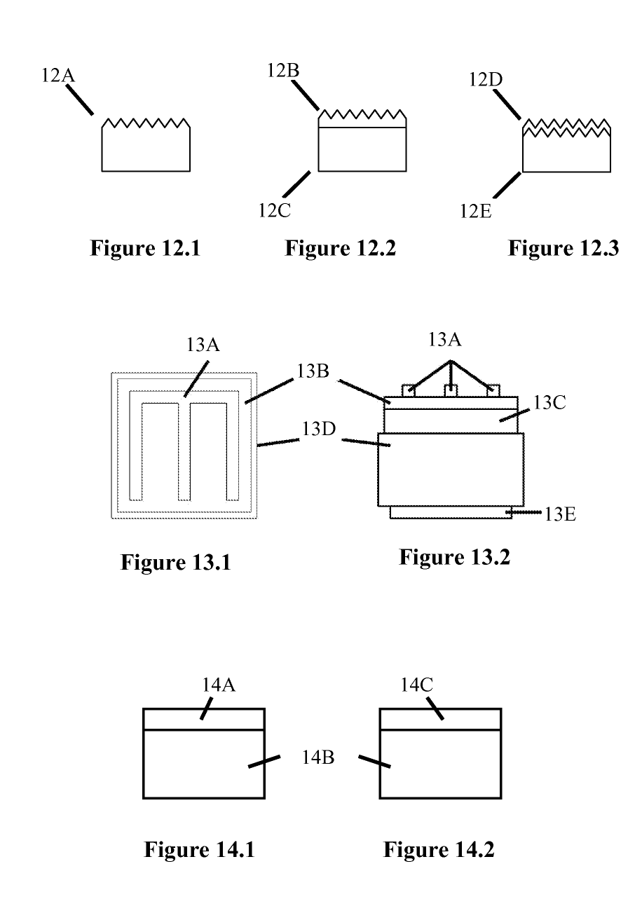

In crystalline silicon solar cells, surface texture is performed using anisotropic etching of the silicon wafer in alkaline solutions such as KOH and, NaOH or TMAH (refer to D. Iencinella et al., doi:10.1016/j.solmat.2004.09.020). In multi-crystalline, it is performed with a combination of masked reactive ion etching and acid wet etching (L. A. Dobrzański et al. Journal of Achievements in Materials and Manufacturing Engineering 31, 77 (2008)). Other types of solar cell use similar approaches to surface texturing. Virtually any type of known method of silicon etching may be applied to texturing the described devices. FIG. 12.1 is a schematic representation of a photovoltaic device with conventional chemically/mechanically textured silicon 12A.

One strategy provided is to avoid cost by texturing organics instead of silicon. Organic are softer materials therefore organics may be indented by stamping with a mold, modifying deposition conditions so that the organic forms a rough and hence automatically textured surface. FIG. 12.2 is a schematic representation of a photovoltaic device with an organic layer 12B deposited on a silicon layer 12C. The organic layer 12B is formed with a textured surface. In this example, the silicon layer 12C does not have a textured surface. A combination of texturing both silicon layer and organic layers may be also used, where texturing of silicon is performed using traditional approaches and the texturing of organic is performed using indentation by a mold and/or modifying deposition conditions so that the organic forms a rough and hence automatically textured surface. FIG. 12.3 is a schematic representation of a photovoltaic device with an organic layer 12D deposited on a silicon layer 12E. The organic layer 12D is formed with a textured surface as discussed above. The silicon layer 12E is also formed with a textured surface (e.g., conventional chemically/mechanically textured). Alternatively, the organic deposited on top of the textured silicon surface could itself have a smooth surface.

Absorption of the electromagnetic radiation in heterojunction devices demonstrated herein happens in the silicon layer. To allow the radiation to reach silicon without substantial losses, one of the electrodes needs to be at least partially transparent, i.e. allow light to pass through. In the devices explained herein for example, the anode is semi-transparent and composed of two layers. One layer is composed of the conducting polymer PEDOT:PSS [Poly(3,4-ethylenedioxythiophene) poly(styrenesulfonate)] and the second is a grid made from an opaque electrode which could be a metal (see e.g., FIGS. 13.1, 13.2). While the discontinuous metal-grid shadows some of the radiation (1% to 40%), it enhances the electrical energy output of the photovoltaic device by reducing the electrical resistance of the current path. To obtain optimum performance from the anode stack, the properties of both PEDOT:PSS layer and metal-grid may be optimized.

Bare silicon layers have unsatisfied silicon valencies, causing midgap defect states which act as recombination centers severely degrading the performance of photovoltaic devices. In conventional photovoltaic devices thermal oxide layers or silicon nitride layers are used to reduce the recombination centers, e.g., passivate the surface. However, this process requires high temperatures and specialized ultra-clean equipment. Organic material can be deposited on bare silicon substrates to passivate silicon at greatly reduced cost.

PQ is an organic molecule that is effective in passivating silicon (S. Avasthi et al., Applied Physics Letters 96, 222109 (2010) doi: 10.1063/1.3429585 and S. Avasthi et al., Surface Science (2011) doi:10.1016/j.susc.2011.04.024). However, it is conceived that organic molecules offer a vast array of potential passivation layers. PQ was selected because it is a n-electron conjugated system and is thought to work like a semi-conductor with a large band gap. Any organic with similar characteristics may be used to passivate silicon. FIG. 14.1 is a schematic representation of a portion of photovoltaic device with a conventional passivation layer. The device has a conventional passivation layer 14A, e.g. silicon-nitride, silicon-oxide and the like, deposited on a silicon layer 14B. FIG. 14.2 is a schematic representation of a portion of photovoltaic device with passivation by an organic layer, such as PQ. The device has an organic passivation layer 14C formed on the silicon layer 14B. The passivation layer is configured to block at least one carrier.

The process of passivation using PQ, entails depositing an organic layer on bare silicon using thermal evaporation in a high vacuum. Prior to deposition, the silicon surface is thoroughly cleaned using established solvents and RCA clean (e.g., the wafers are prepared by soaking them in DI water, then cleaned with a 1:1:5 solution of ammonium hydroxide, hydrogen peroxide, and water at 75 or 80° C. for about 15 minutes, followed by a short 1 min immersion in a 1:100 solution of HF+water at 25° C., followed by a 15 minute wash with a 1:1:5 solution of hydrogen chloride, hydrogen peroxide and water at 75 or 80° C.). This is followed by a short (e.g., 1 min.) 1:100 HF: deionized water dip to strip the oxide layer formed during the previous cleaning steps. The silicon is then loaded into an evaporation system with a base pressure of <5×10⁻⁷ torr. Once at base pressure, the organic layer is then thermally deposited at very low deposition rates (0.2-0.3 A/s). The system is left in the chamber under vacuum for 12 hours to let the organic layer react with the silicon surface and passivate it.

### Example

Manufacture of a metal-organic-silicon heterojunction on n-type silicon with no p-n junction and P3HT as an electron-blocking layer.

FIG. 8.2 is a schematic diagram showing the structure of the metal-P3HT-silicon heterojunction photovoltaic device embodiment. The device has an anode 8B (metal grid), a transparent conductor (part of anode) 8D, an organic electron blocking layer (P3HT) 8E, an n-type silicon layer 8A and a cathode electrode 8C. The curve 8I in FIG. 8.3 shows the current-voltage characteristics of the photovoltaic devices of 8.2.

The method of manufacture starts with a silicon substrate. The substrate is carefully cleaned using standard silicon cleaning methodologies. Any known cleaning methodology may be used. For example, rinsing in acetone/methanol/propanol-2 and then RCA cleaning (e.g., The wafers are prepared by soaking them in DI water, then cleaned with a 1:1:5 solution of ammonium hydroxide, hydrogen peroxide, and water at 75 or 80° C. for about 15 minutes; followed by a short immersion in a 1:100 solution of HF+water at 25° C., followed by a wash with a 1:1:5 solution of hydrogen chloride hydrogen peroxide, and water at 75 or 80° C.). This is followed by dipping the silicon in dilute HF (about 1:100) to remove the chemical oxide coating on the surface. Immediately after the surface is cleaned and prepared, a solution of the organic material, to be used in the heterojunction, in an appropriate solvent is spin coated on one of the silicon surfaces. For instance, P3HT dissolved in chlorobenzene may be spin-coated onto the top surface of a cleaned and prepared surface of crystalline silicon wafer. Once the organic layer has dried in air, the top and bottom electrodes are deposited. Any suitable electrode may be used. Not to be limited by example, suitable metal electrodes include Pd and Al and similar metals. To allow light transmission through the anode a transparent conductive organics is deposited. Such a transparent electrode includes but is not limited to, Poly(3,4-ethylenedioxythiophene) polystyrenesulfate (hereinafter, referred to as PEDOT:PSS). Depending on the structure some thermal treatments may be applied to improve efficiencies. Not to be limited by example, typical treatments involve heating the samples at between about 3° C. to about 15° C. for about 0 to about 10 mins. Thermal treatments are typically conducted under vacuum or in an oxygen/moisture-deficient environment. Such devices achieve a high open-circuit voltage of 0.59V under 100 mW/cm2 of light excitation. The short-circuit current is 29 mA/cm2 and the fill factor is 0.59, translating to an energy efficiency of 10.1%.

Although features and elements are described above in particular combinations, each feature or element may be used alone without the other features and elements or in various combinations with or without other features and elements.

What is claimed is:

1. A photovoltaic device comprising:
a silicon layer and first and second organic layers, the silicon layer having a first face and a second face;
first and second electrodes electrically coupled to the first and second organic layers;
a first heterojunction formed at a junction between the one of the faces of the silicon layer and the first organic layer; and
a second heterojunction formed at a junction between one of the faces of the silicon layer and the second organic layer.

2. The photovoltaic device of claim 1, wherein at least one organic layer is configured as an electron-blocking layer.

3. The photovoltaic device of claim 1, wherein at least one organic layer is configured as a hole-blocking layer.

4. The photovoltaic device of claim 1, wherein at least one organic layer is comprised of phenanthrenequinone (PQ).

5. The photovoltaic device of claim 1, further comprising a passivating layer disposed between at least one of the organic layers and the silicon layer.

6. The photovoltaic device of claim 5, wherein the passivating layer is organic.

7. The photovoltaic device of claim 1, wherein at least one of the organic layers passivates a surface of the silicon layer.

8. The photovoltaic device of claim 1, further comprising at least one transparent electrode layer coupled to at least one of the electrodes.

9. A photovoltaic device comprising:
a silicon layer in contact with an organic layer configured to form a heterojunction; and
a first electrode electrically coupled to the silicon layer and a second electrode electrically coupled to the organic layer, the organic layer being configured as a charge carrier blocking layer.

10. The photovoltaic device of claim 9, further comprising a p-n junction formed in the silicon.

11. The photovoltaic device of claim 9, wherein the organic layer is undoped and the organic layer is solution processed.

12. The photovoltaic device of claim 9, wherein the organic layer comprises Poly 3-Hexythiophene (P3HT).

13. The photovoltaic device of claim 9, further comprising a passivation layer disposed between the organic layer and the silicon layer.

14. The photovoltaic device of claim 13, wherein the passivation layer is formed of an organic.

15. The photovoltaic device of claim 9, wherein the organic layer is a passivation layer.

16. The photovoltaic device of claim 9, wherein the organic layer comprises phenanthrenequinone (PQ).

17. The photovoltaic device of claim 9, further comprising at least one transparent electrode layer coupled to at least one of the electrodes.

18. A photovoltaic device comprising:
a silicon layer and an organic layer configured to form a heterojunction; and
a first electrode electrically coupled to the silicon layer and a second electrode electrically coupled to the organic layer, the silicon layer being formed of materials selected from the group consisting of: silicon alloys, multicrystalline silicon, microcrystalline silicon, protocrystalline silicon, upgraded metallurgical-grade silicon, ribbon silicon, thin-film silicon and combinations thereof.

19. The photovoltaic device of claim 18, wherein the organic layer is configured as an electron-blocking layer.

20. The photovoltaic device of claim 18, wherein the organic layer is configured as a hole-blocking layer.

21. The photovoltaic device of claim 18, wherein the organic layer is comprised of phenanthrenequinone (PQ).

22. The photovoltaic device of claim 18, further comprising a passivating layer disposed between the organic layer and the silicon layer.

23. The photovoltaic device of claim 22, wherein the passivating layer is organic.

24. The photovoltaic device of claim 18, wherein the organic layer passivates a surface of the silicon layer.

25. The photovoltaic device of claim 18, further comprising at least one transparent electrode layer coupled to at least one of the electrodes.

26. A photovoltaic device comprising:
a silicon layer in contact with an organic layer to form a heterojunction; and
a first electrode electrically coupled to the organic layer and a second electrode electrically coupled to the silicon layer, the silicon layer being formed with a textured surface.

27. The photovoltaic device of claim 26, wherein the organic layer is formed with a textured surface.

28. The photovoltaic device of claim 26, wherein the textured surface of the organic layer conforms to the textured surface of the silicon layer.

29. The photovoltaic device of claim 26, further comprising a second organic layer in contact with the silicon layer to form a second heterojunction, the second electrode being electrically coupled to the silicon layer via the second organic layer.

30. A photovoltaic device comprising:
a silicon layer in contact with an organic layer configured to form a heterojunction; and
a first electrode electrically coupled to the organic layer and a second electrode electrically coupled to the silicon layer, the organic layer being formed with a textured surface.

31. The photovoltaic device of claim 30, further comprising a second organic layer in contact with the silicon layer to form a second heterojunction, the second electrode being electrically coupled to the silicon layer via the second organic layer.

32. A photovoltaic device comprising:
a silicon layer in contact with an organic layer configured to form a heterojunction; and
a first electrode electrically coupled to the silicon layer and a second electrode electrically coupled to the organic layer, wherein the organic layer is composed on the silicon layer such that a highest occupied molecular orbital (HOMO) of the organic layer aligns with the top of the valence band edge (Ev) of the silicon layer to facilitate transmission of holes and the lowest unoccupied molecular orbital (LUMO) of the organic layer does not align with the bottom of the conduction band (Ec) of the silicon layer.

33. A photovoltaic device comprising:
a silicon layer in contact with an organic layer configured to form a heterojunction; and
a first electrode electrically coupled to the silicon layer and a second electrode electrically coupled to the organic layer, wherein the organic layer is composed on the silicon layer such that the lowest unoccupied molecular orbital (LUMO) of the organic layer aligns with the bottom of the conduction band edge (Ec) of the silicon layer to facilitate transmission of electrons and the highest occupied molecular orbital (HOMO) of the organic layer does not align with the top of the valence band edge (Ev) of the silicon layer.

34. A photovoltaic device comprising:
a silicon layer in contact with an organic layer configured to form a heterojunction and passivate a surface of the silicon; and
a pair of electrodes defining a current path through the silicon layer, wherein the organic layer is disposed outside of the current path.

35. The photovoltaic device of claim 34, wherein the organic layer blocks at least one charge carrier.

36. The photovoltaic device of claim 34, wherein the organic layer comprises phenanthrenequinone (PQ).

37. A method of forming a photovoltaic device, the method comprising:
depositing first and second organic layers on a silicon layer, the silicon layer having a first face and a second face; and
electrically coupling first and second electrodes electrically to the first and second organic layers, wherein a first heterojunction is formed at a junction between the first face of the silicon layer and the first organic layer and a second heterojunction is formed at a junction between the second face of the silicon layer and the second organic layer.

38. The method of claim 37, wherein the photovoltaic device is fabricated at a temperature below 500° C.

39. A method of forming a photovoltaic device, the method comprising:
depositing an organic layer on a silicon layer and forming a heterojunction; and
electrically coupling a first electrode to the silicon layer and electrically coupling a second electrode to the organic layer, the organic layer being configured as a charge carrier blocking layer.

40. The method of claim 39, wherein the photovoltaic device is fabricated at a temperature below 500° C.

41. A method of forming a photovoltaic device, the method comprising:
depositing an organic layer on a silicon layer and forming a heterojunction; and
electrically coupling a first electrode to the silicon layer and electrically coupling a second electrode to the organic layer, wherein the silicon layer is formed of materials selected from the group consisting of: silicon carbide, multicrystalline silicon, microcrystalline silicon, protocrystalline silicon, upgraded metallurgical-grade silicon, ribbon silicon, thin-film silicon and combinations thereof.

42. The method of claim 41, wherein the photovoltaic device is fabricated at a temperature below 500° C.
